(19) United States
(12) Patent Application Publication
(10) Pub. No.: US 2002/0050635 A1
(43) Pub. Date: May 2, 2002

(54) Integrated circuit device

(75) Inventors: Katsuya Ogura, Kyoto-shi (JP); Yoshihiro Ikefuji, Kyoto-shi (JP)

Correspondence Address: RADER FISHMAN & GRAUER, PLLC, Suite 501, 1233 20th Street, N.W., Washington, DC, 20036, US

(73) Assignee: ROHM CO., LTD.

(21) Appl. No.: 09/983,396

(22) Filed: Oct. 24, 2001

(30) Foreign Application Priority Data
Oct. 26, 2000 (JP) 2000-326776

(51) Int. Cl. H01L 23/02

(52) U.S. Cl. 257/686

(57) ABSTRACT

An integrated circuit device having a chip-on-chip structure comprises a first IC chip, a second IC chip arranged on the first IC chip with surfaces of the first and second IC chips facing each other and electrically connected to the first IC chip by way of bonding, one or more conductor materials, and a substrate to which an electric potential is given and on which the first and second IC chips are mounted, wherein the conductor material is arranged either between the first and second IC chips or on an opposite surface of the second IC chip to the surface facing the first IC chip, and electrically connected to the substrate so as to provide a shielding effect for reducing malfunctions of the device that are caused by noise.

### BACKGROUND OF THE INVENTION

1. Field of the Invention

The present invention relates to an integrated circuit device having a plurality of IC (integrated circuit) chips which are electrically connected together by being bonded through bumps thereof or the like.

2. Description of the Prior Art

In a conventional method, it is sometimes the case that two semiconductor chips are mounted in a so-called chip-on-chip structure in which electrical connection and mechanical bonding are achieved between the two semiconductor chips by means of connecting bumps formed thereon together. This chip-on chip structure provides an advantage in reducing a mounting area over a method in which each individual semiconductor chip is mounted separately.

However, in a conventional case as shown in FIG. 7, IC chips 1 and 2 having the chip-on-chip structure are simply stacked on a substrate 5. Because of this arrangement, the IC chips are prone to pick up incoming external noise or one of the IC chips is prone to pick up the noise that is generated inside the other IC chip. The noise thus picked up may cause a malfunction of the device or may make the device inoperable, particularly when the device deals with high frequency signals.

### SUMMARY OF THE INVENTION

An object of the present invention is to provide an integrated circuit device having a chip-on-chip structure capable of reducing malfunctions that are caused by noise.

To achieve the above object, according to one aspect of the present invention, an integrated circuit device having a chip-on-chip structure comprises a first IC chip, a second IC chip arranged on the first IC chip with surfaces of the first and second IC chips facing each other and electrically connected to the first IC chip by way of bonding, a conductor material, and a substrate to which a fixed electric potential is given and on which the first and second IC chips are mounted, wherein the conductor material is arranged either between the first and second IC chips or on a surface of the second IC chip opposite to the surface thereof facing the first IC chip, and is electrically connected to the substrate so as to provide a shielding effect.

In this structure, the shielding effect is enhanced and thereby blocking incoming external noise or internal noise that is generated inside the IC chips.

### BRIEF DESCRIPTION OF THE DRAWINGS

This and other objects and features of the present invention will become clear from the following description, taken in conjunction with the preferred embodiments with reference to the accompanying drawings in which:

FIG. 1 is a schematic cross sectional view showing an integrated circuit device of a first embodiment of the invention;

FIG. 2 is a schematic cross sectional view showing an integrated circuit device of a second embodiment of the invention;

FIG. 3 is a schematic cross sectional view showing an integrated circuit device of a third embodiment of the invention;

FIG. 4 is a schematic cross sectional view showing an integrated circuit device of a fourth embodiment of the invention;

FIG. 5A is a schematic cross sectional view showing an integrated circuit device of a fifth embodiment of the invention;

FIG. 5B is a schematic top view showing the integrated circuit device of the fifth embodiment of the invention;

FIG. 6A is a schematic cross sectional view showing an integrated circuit device of a sixth embodiment of the invention;

FIG. 6B is a schematic top view showing the integrated circuit device of the sixth embodiment of the invention; and

FIG. 7 is a schematic sectional view showing a conventional integrated circuit device having a chip-on-chip structure.

### DESCRIPTION OF THE PREFERRED EMBODIMENTS

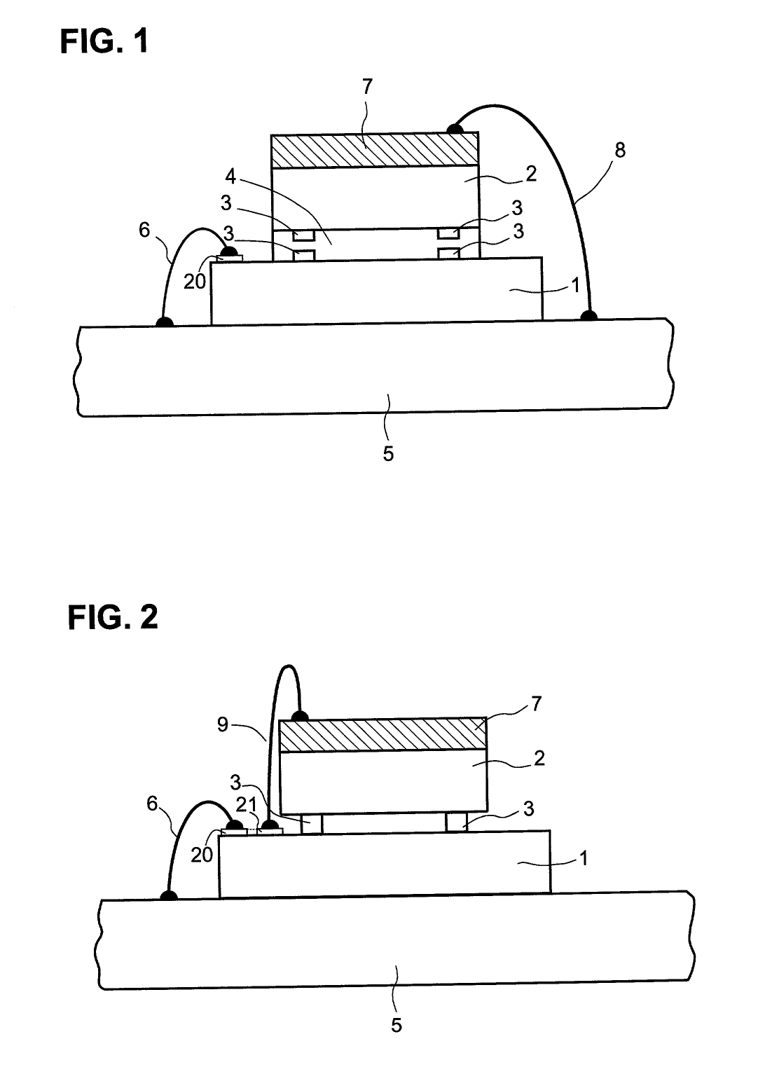

Hereinafter, embodiments of the present invention will be described with reference to the accompanying drawings. Although a plurality of bumps are formed on a surface of an IC chip 1 of each embodiment, these bumps and wires connected thereto are not illustrated in FIGS. 1 to 6B for easy reading of the drawings. Such identical components as are found also in another illustration are identified with the same reference numerals, and overlapping descriptions will not be repeated.

FIG. 1 is a schematic cross sectional view showing an integrated circuit device of a first embodiment of the invention. A chip-on-chip structure is achieved by electrically connecting an IC chip 1 and an IC chip 2 together by means of bumps 3 that are made of gold or the like. To achieve this, an anisotropic conductive film 4 is sandwiched between the IC chips, and heat and pressure are applied thereto in a direction of bonding for turning the anisotropic conductive film 4 conductive only in the direction of bonding so that an electrical connection between the IC chips via the bumps 3 is achieved. Thereafter, the chips are sealed in a resin mold and finished in packaging, or the chips are sealed in a potted resin. As these finishing processes are widely known, descriptions thereof will be omitted.

The IC chip 1 is mounted on a substrate 5 with a flip side thereof (a side opposite to a side to which the IC chip 2 is coupled) facing the substrate 5. The IC chip 1 is electrically connected to the substrate 5 with a wire 6 having one end thereof connected to a pad 20. The substrate 5 is connected to ground. It is possible to use, as the substrate 5, a metal island formed as a part of a resin-sealed IC, a resin board comprising metal conductors that are formed thereon, or the like.

On an upper side of the IC chip 2 (opposite to a side to which the IC chip 1 is coupled) is formed a conductor material 7. The conductor material 7 can be formed through an evaporation or bonding process using such a material as cupper, aluminum, gold, or the like. The conductor material 7 is electrically connected with a wire 8 to the substrate 5 that maintains a ground potential. This structure serves to enhance immunity of the device against noise, particularly the noise intruding from outside.

FIG. 2 is a schematic cross sectional view showing an integrated circuit device of a second embodiment of the invention. As shown in the illustration, it is also possible to electrically connect a conductor material 7 to a substrate 5 with a wire 9 that is connected to an IC chip 1 through a pad 21 formed thereon and then with a wire 6 that connects a pad 20, which is connected to the pad 21 with a conductor, to the substrate 5. The structure provided in this embodiment serves to enhance immunity of the device against noise, particularly the noise intruding from outside. This structure also serves to prevent the connecting wire which otherwise becomes longer from breaking, slacking, and an accidental electrical contact inside the device. This structure does not require a long single wire for connection which would otherwise work unnecessarily as an antenna for picking up noise and turn the device less immune to noise. It is to be noted that FIG. 2 shows a structure in which the IC chips 1 and 2 are directly coupled together with bumps 3.

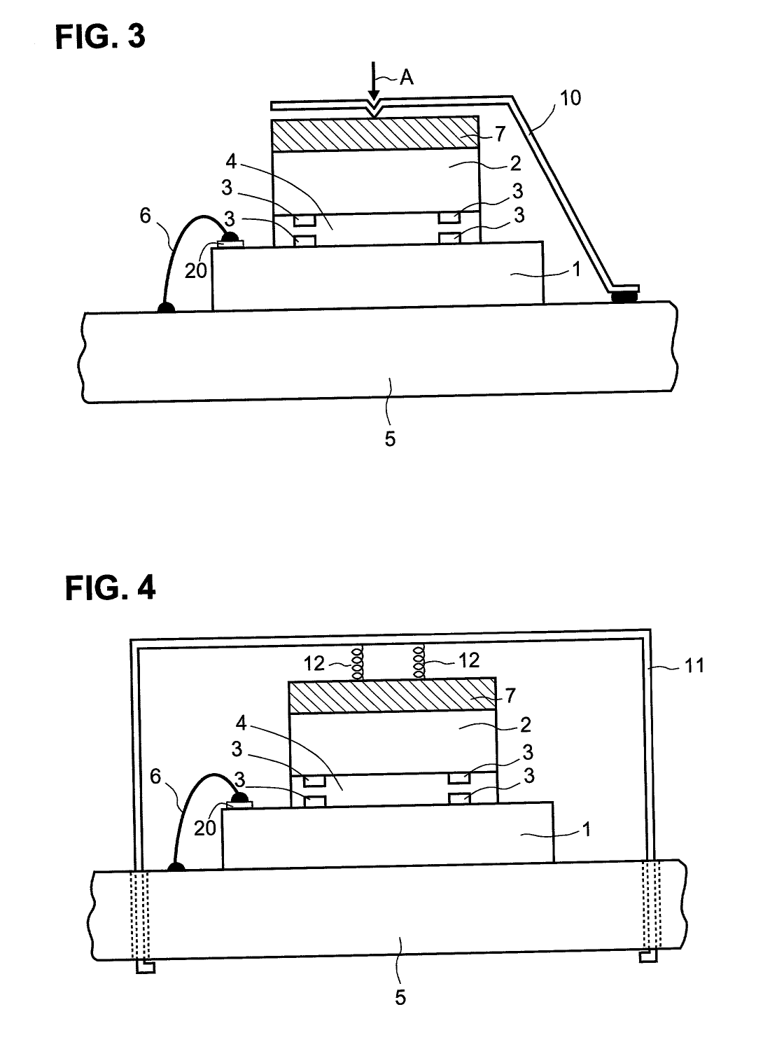

FIG. 3 is a schematic cross sectional view showing an integrated circuit device of a third embodiment of the invention. As illustrated, it is also possible to use a plate spring 10 made of metal for connecting a conductor material 7 to a substrate 5. In this structure, the plate spring 10 is made contact with a conductor material 7 at one end, and is bonded or welded with a conductive material to a substrate 5 at another end. The plate spring 10 used in this embodiment serves to provide a more reliable connection. Furthermore, it is also possible to use a wider plate spring for the plate spring 10, substantially as wide as a depth of an IC chip 2, thereby further enhancing a shielding effect.

FIG. 4 is a schematic cross sectional view showing an integrated circuit device of a fourth embodiment of the invention. As illustrated, it is also possible to substantially enclose IC chips 1 and 2 with a conductor casing 11 for connecting a conductor material 7 to a substrate 5. Bottom portions of the conductor casing 11 are inserted into a substrate for securing electrical and mechanical connections. Furthermore, springs 12 that are conductive and pressed against tension (exerting an expanding force) may be used for electrically connecting the conductor casing 11 to the conductor material 7. It is desirable if the conductor casing 11 has a shape so as to hermetically enclose the IC chips 1 and 2 so that a shielding effect will be further enhanced. In this structure, bonding and welding processes are simplified and yet electrical connections are further secured.

In the aforementioned embodiments as shown in FIGS. 3 and 4, if the plate spring 10 in the case of FIG. 3 and the conductor casing 11 in the case of FIG. 4 serve to provide a sufficient shielding effect, then the plate spring 10 in FIG. 3 or the springs 12 in FIG. 4 may be arranged so as to make a direct contact with the upper face of the IC chip 2 omitting the conductor material 7.

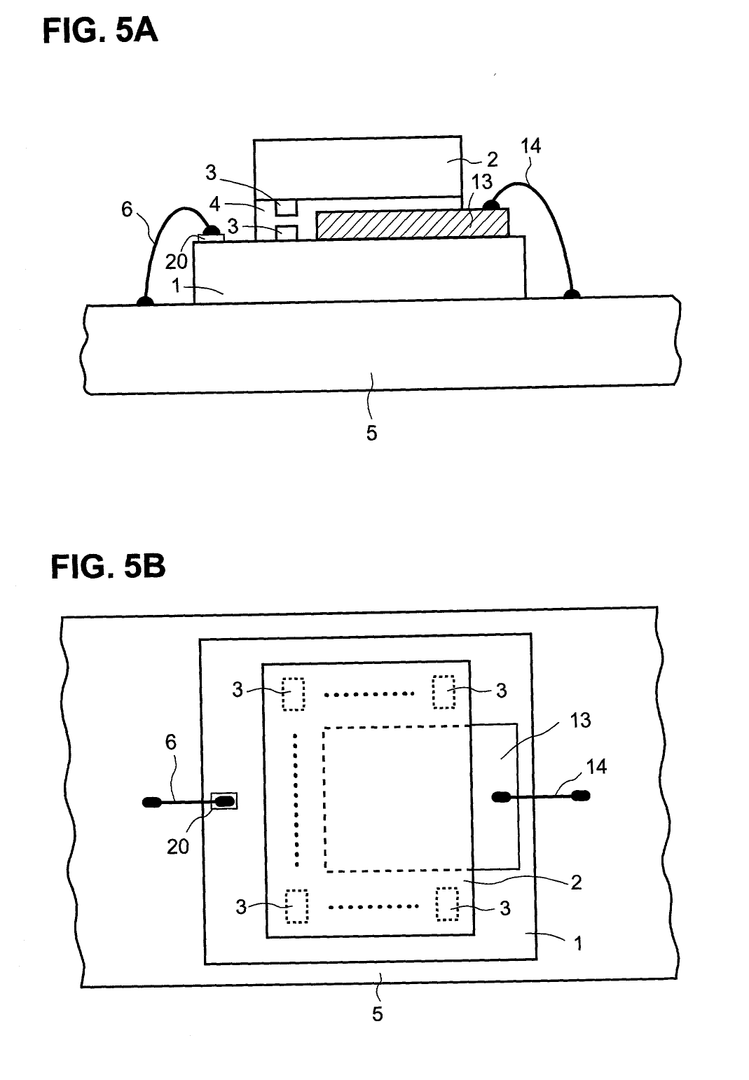

FIG. 5A is a schematic cross sectional view showing an integrated circuit device of a fifth embodiment of the invention. FIG. 5B is a schematic top view showing the integrated circuit device of the fifth embodiment. In this embodiment, avoiding a direct contact with the bumps 13, a conductor material 13 made of metal is sandwiched or inserted in an anisotropic conductive film 4 between IC chips 1 and 2 having a chip-on-chip structure. A portion of the conductor material 13 protrudes from the anisotropic conductive film 4. This portion is then electrically connected with a wire 14 to a substrate 5 that maintains a ground potential. It is also possible to connect the conductor material 13 to the substrate 5 with wires routed via the IC chip 1 or with such a plate spring as the plate spring 10 as shown in FIG. 3. In this embodiment, the conductor material 13 placed between the IC chips 1 and 2 serves to provide a further enhanced shielding effect against interfering noise, particularly the noise generated internally as well as externally.

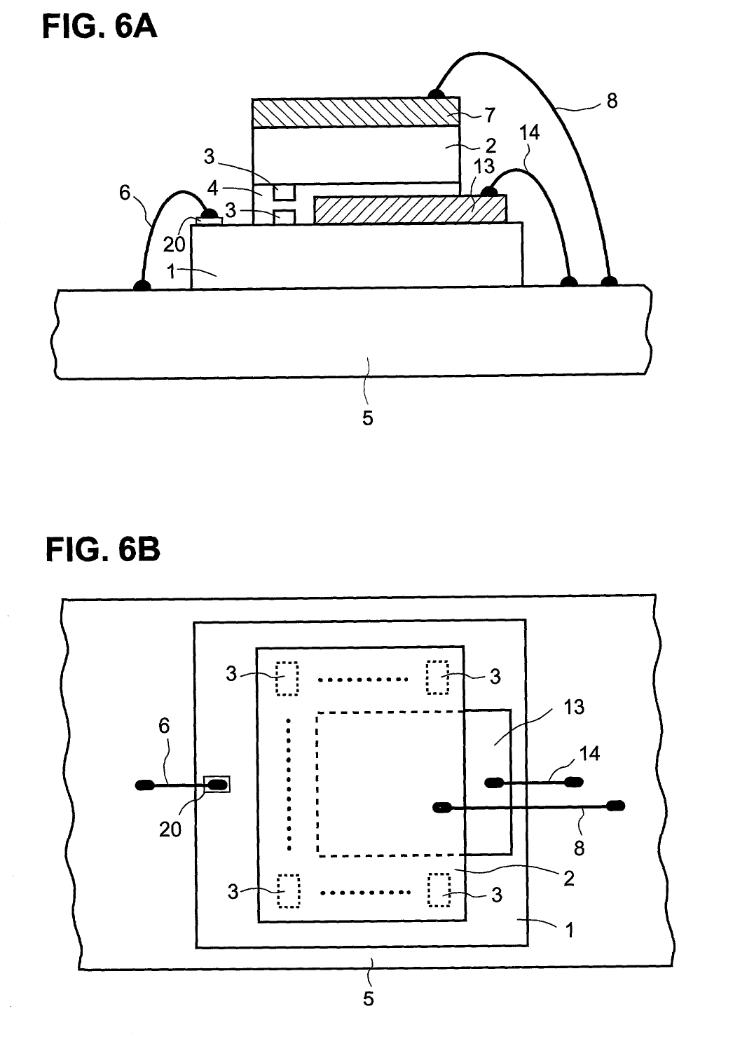

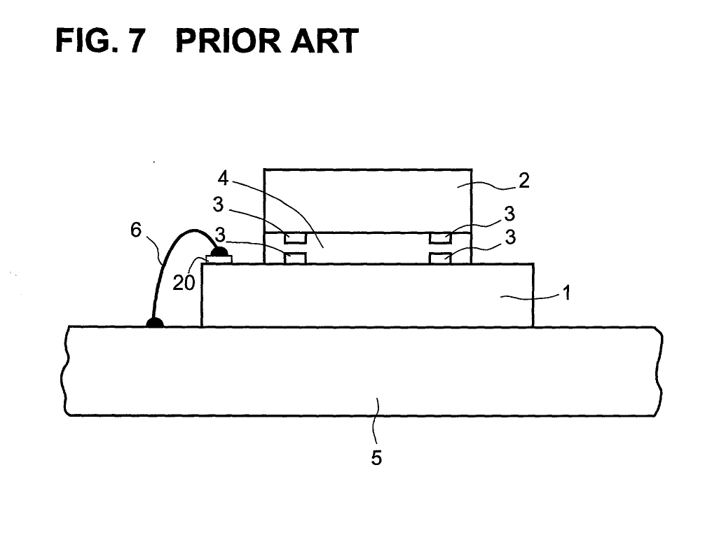

FIG. 6A is a schematic cross sectional view showing an integrated circuit device of a sixth embodiment of the invention. FIG. 6B is a schematic top view showing the integrated circuit device of the sixth embodiment. As shown in these illustrations, it is also possible to combine the two structures shown in FIG. 1, and FIG. 5A and 5B so that a new structure has both the conductor materials 7 and 13 for an additional enhancement of the shielding effect.

Although each of the embodiments described previously deals with connecting the conductor materials 7 and 11, the conductor casing 13, and the plate spring 11 to the ground potential, it is also possible to connect these to another point having a fixed potential (e.g. a voltage supply line).

As described above, according to the integrated circuit device in the present invention, an shielding effect is realized in the device by employing and connecting at least one conductor material to a fixed potential point. In this way, the noise intruding from outside or generated inside the IC chips and interfering the device is suppressed, thereby contributing to reducing malfunctions resulting from the noise.

What is claimed is:

1. An integrated circuit device having a chip-on-chip structure, comprising;
a first IC chip;
a second IC chip arranged on the first IC chip with surfaces of the first and second IC chips facing each other and electrically connected to the first IC chip by way of bonding;
a conductor material; and
a substrate to which a fixed electric potential is given and on which the first and second IC chips are mounted;
wherein the conductor material is arranged either between the first and second IC chips or on a surface of the second IC chip opposite to the surface thereof facing the first IC chip, and is electrically connected to the substrate so as to provide a shielding effect.

2. An integrated circuit device having a chip-on-chip structure as claimed in claim 1,
wherein the conductor material is connected to the substrate with a wire.

3. An integrated circuit device having a chip-on-chip structure as claimed in claim 1,
wherein the conductor material is connected to the substrate with wires via pads formed on the first IC chip.

4. An integrated circuit device having a chip-on-chip structure as claimed in claim 1,
wherein the conductor material is connected to the substrate with a conductive plate spring.

5. An integrated circuit device having a chip-on-chip structure as claimed in claim 1,
wherein the conductor material is connected to the substrate with a conductive casing via conductive springs.

6. An integrated circuit device having a chip-on-chip structure, comprising;
a first IC chip;
a second IC chip arranged on the first IC chip with surfaces of the first and second IC chips facing each other and electrically connected to the first IC chip by way of bonding;
one or more conductor materials; and
a substrate to which a fixed electric potential is given and on which the first and second IC chips are mounted;
wherein the conductor materials are arranged both between the first and second IC chips and on a surface of the second IC chip opposite to the surface thereof facing the first IC chip, and are electrically connected to the substrate so as to provide a shielding effect.

7. An integrated circuit device having a chip-on-chip structure as claimed in claim 6,
wherein the conductor materials are connected to the substrate with wires.

8. An integrated circuit device having a chip-on-chip structure as claimed in claim 6,
wherein at least one of the conductor materials is connected to the substrate with wires via pads formed on the first IC chip.

9. An integrated circuit device having a chip-on-chip structure as claimed in claim 6,
wherein at least one of the conductor materials is connected to the substrate with a conductive plate spring.

10. An integrated circuit device having a chip-on-chip structure as claimed in claim 6,
wherein at least one of the conductor materials is connected to the substrate with a conductive casing via conductive springs.
